(19) United States
(12) Patent Application Publication
(10) Pub. No.: US 2014/0203408 A1
(43) Pub. Date: Jul. 24, 2014

(54) METHOD OF PRODUCING COMPOSITE WAFER AND COMPOSITE WAFER

(71) Applicants: NATIONAL INSTITUTE OF ADVANCED INDUSTRIAL SCIENCE AND TECHNOLOGY, Tokyo (JP); SUMITOMO CHEMICAL COMPANY, LIMITED, Tokyo (JP)

(72) Inventors: Tomoyuki TAKADA, Tsukuba-shi (JP); Hisashi YAMADA, Tsukuba-shi (JP); Masahiko HATA, Tsukuba-shi (JP); Tatsuro MAEDA, Tsukuba-shi (JP); Taro ITATANI, Tsukuba-shi (JP); Tetsuji YASUDA, Tsukuba-shi (JP)

(73) Assignees: NATIONAL INSTITUTE OF ADVANCED INDUSTRIAL SCIENCE AND TECHNOLOGY, Tokyo (JP); SUMITOMO CHEMICAL COMPANY, LIMITED, Tokyo (JP)

(21) Appl. No.: 14/220,669

(22) Filed: Mar. 20, 2014

Related U.S. Application Data
(63) Continuation-in-part of application No. PCT/JP2012/006027, filed on Sep. 21, 2012.

(30) Foreign Application Priority Data
Sep. 22, 2011 (JP) 2011-208224
Sep. 22, 2011 (JP) 2011-208225
Jun. 1, 2012 (JP) 2012-126621
Jun. 1, 2012 (JP) 2012-126622

(51) Int. Cl. H01L 29/06; H01L 21/306

(52) U.S. Cl. CPC H01L 29/06; H01L 21/306
USPC 257/618; 438/458

(57) ABSTRACT

There is provided a method that includes forming a sacrificial layer and the semiconductor crystal layer on a semiconductor crystal layer formation wafer in the stated order, bonding together the semiconductor crystal layer formation wafer and a transfer-destination wafer such that a first surface of the semiconductor crystal layer and a second surface of the transfer-destination wafer face each other, and splitting the transfer-destination wafer from the semiconductor crystal layer formation wafer with the semiconductor crystal layer remaining on the transfer-destination wafer side, by etching away the sacrificial layer by immersing the semiconductor crystal layer formation wafer and the transfer-destination wafer wholly or partially in an etchant. Here, the transfer-destination wafer includes an inflexible wafer and an organic material layer, and a surface of the organic material layer is the second surface.

The contents of the following Japanese and PCT patent applications are incorporated herein by reference:
NO. 2011-208224 filed on Sep. 22, 2011,
NO. 2011-208225 filed on Sep. 22, 2011,
NO. 2012-126621 filed on Jun. 1, 2012,
NO. 2012-126622 filed on Jun. 1, 2012, and
PCT/JP2012/006027 filed on Sep. 21, 2012.

### BACKGROUND

1. Technical Field

The present invention relates to a composite wafer and a producing method thereof.

2. Related Art

Group III-V compound semiconductors such as GaAs and InGaAs have a high electron mobility, whereas Group IV semiconductors such as Ge and SiGe have a high hole mobility. Therefore, a high-performance CMOSFET (Complementary Metal-Oxide-Semiconductor Field Effect Transistor) can be realized by using a Group III-V compound semiconductor to make an N-channel MOSFET (Metal-Oxide Semiconductor Field Effect Transistor, hereunder an N-channel MOSFET may be referred to as simply an “nMOSFET”) and using a Group IV semiconductor to make a P-channel MOSFET (hereunder a P-channel MOSFET may be referred to as simply a “pMOSFET”). Non-patent Document No. 1 discloses a CMOSFET structure in which a N-channel MOSFET whose channel is made of a Group III-V compound semiconductor and a P-channel MOSFET whose channel is made of Ge are formed on a single wafer.

In order to fabricate a N-channel MISFET (Metal-Insulator-Semiconductor Field Effect Transistor, hereunder a N-channel MISFET may be referred to as simply an “nMISFET”) whose channel is made of a Group III-V compound semiconductor and a P-channel MISFET (hereunder may be referred to as simply a “pMISFET”) whose channel is made of a Group IV semiconductor on a same single wafer, it is necessary to develop a technology to fabricate the Group III-V compound semiconductor for the nMISFET and the Group IV semiconductor for the pMISFET on a single wafer. Moreover, considering that a device is fabricated as a LSI (Large Scale Integration), it is preferable that the Group III-V compound semiconductor crystal layer for the nMISFET and the Group IV semiconductor crystal layer for pMISFET are formed on a silicon wafer to which conventional manufacturing apparatus and conventional processes are applicable.

For example, as a technology to fabricate different types of materials such as a Group III-V compound semiconductor layer and a Group IV semiconductor crystal layer on a single wafer (for example, a silicon wafer), a technique to transfer a semiconductor crystal layer formed on a crystal growth wafer to a transfer-destination wafer to which the semiconductor crystal layer is transferred has been known. For instance, Non-patent Document No. 2 describes a technique in which an AlAs layer as a sacrificial layer is formed on a GaAs wafer and a Ge layer formed on the sacrificial layer (the AlAs layer) is transferred to a Si wafer. The above-mentioned Non-patent Document No. 1 is S. Takagi, et al., SSE, vol. 51, pp. 526-536, 2007, and Non-patent Document No. 2 is Y. Bai and E. A. Fitzgerald, ECS Transactions, 33 (6) 927-932 (2010).

According to the technique described in Non-patent Document No. 2, the AlAs layer as the sacrificial layer is removed by etching, and the Ge layer which is a semiconductor crystal layer to be transferred is split from the GaAs wafer which is the crystal growth wafer. However, the sacrificial layer is provided between the crystal growth wafer and the Ge layer and it is removed by lateral direction etching performed in a gap between the crystal growth wafer and the Ge layer, and therefore when the thickness of the sacrificial layer is thin, an etchant cannot be sufficiently supplied thereto and it may takes time to remove the sacrificial layer.

When a thick sacrificial layer is formed, an etchant can be smoothly supplied thereto and an amount of time consumed for the removal of the sacrificial layer can be shortened. However, a thick sacrificial layer can degrades the quality of the semiconductor crystal layer formed on the sacrificial layer. Moreover, it is preferable that the flatness of the semiconductor crystal layer be maintained in order to secure a firm adhesion to a transfer-destination wafer. However, when the thickness of the sacrificial layer is increased, the flatness of the surface of the thick sacrificial layer tends to be low and consequently the flatness of the semiconductor crystal layer formed on the sacrificial layer becomes low.

In addition, the semiconductor crystal layer that has been transferred from the crystal growth wafer to a transfer-destination wafer may be further transferred to another transfer-destination wafer. Here, an adhesion layer (or adhesion mechanism) provided between the transfer-destination wafer and the semiconductor crystal layer when the semiconductor crystal layer is transferred from the crystal growth wafer to the transfer-destination wafer is then utilized as a sacrificial layer (or detachment mechanism) when the semiconductor crystal layer is further transferred from the transfer-destination wafer to a next transfer-destination wafer. Therefore an and a material of the adhesion layer (sacrificial layer) used for each transfer (or an adhesive mechanism used for each transfer) should be adequately selected to obtain appropriate adhesive strengths. In order to increase freedom of selection, it is preferable that the physical property (adhesion strength and the like) of the adhesion layer (sacrificial layer) be dynamically changeable and controllable.

It is an object of the invention to provide a technique to increase an etching rate of the sacrificial layer used when the semiconductor crystal layer formed on the crystal growth wafer is transferred to a transfer-destination wafer. It is another object of the invention to control adhesiveness of the adhesion layer or sacrificial layer when transfer is performed.

### SUMMARY

According to the first aspect related to the present invention, provided is one exemplary method of producing a composite wafer including a semiconductor crystal layer. The method includes forming, in order, a sacrificial layer and the semiconductor crystal layer directly or indirectly on a semiconductor crystal layer formation wafer; bonding together the semiconductor crystal layer formation wafer and a transfer-destination wafer such that a first surface, which is a surface of a layer formed directly or indirectly on the semiconductor crystal layer formation wafer, and a second surface, which is a surface of the transfer-destination wafer or of a layer formed directly or indirectly on the transfer-destination wafer and is to be in contact with the first surface, face each other; and splitting the transfer-destination wafer from the semiconductor crystal layer formation wafer with the semiconductor crystal layer remaining on the transfer-destination wafer by etching away the sacrificial layer by immersing the semiconductor crystal layer formation wafer and the transfer-destination wafer wholly or partially in an etchant. In this case, the transfer-destination wafer includes an inflexible wafer and an organic material layer, and a surface of the organic material layer is the second surface.

According to the second aspect related to the present invention, provided is a method of producing a composite wafer including a semiconductor crystal layer. The method includes forming a sacrificial layer and the semiconductor crystal layer directly or indirectly on a semiconductor crystal layer formation wafer in an order that the sacrificial layer is firstly formed and the semiconductor crystal layer is then formed; forming, directly or indirectly on the semiconductor crystal layer, an adhesion layer made of an organic material; bonding together the semiconductor crystal layer formation wafer and a transfer-destination wafer such that a first surface, which is a surface of the adhesion layer, and a second surface, which is a surface of the transfer-destination wafer or of a layer formed directly or indirectly on the transfer-destination wafer and is to be in contact with the first surface, face each other; and separating the transfer-destination wafer from the semiconductor crystal layer formation wafer with the semiconductor crystal layer remaining on the transfer-destination wafer, by etching away the sacrificial layer by immersing the semiconductor crystal layer formation wafer and the transfer-destination wafer wholly or partially in an etchant.

In the first and second aspects, the semiconductor crystal layer may be made of GeₓSi₁₋ₓ (0<x≦1). It is preferable that the thickness of the semiconductor crystal layer be equal to or larger than 0.1 nm and smaller than 1 μm. The method may further include, after forming the sacrificial layer and the semiconductor crystal layer and before bonding together the semiconductor crystal layer formation wafer and the transfer-destination wafer, forming an adhesion layer made of an organic material on the semiconductor crystal layer. In this case, a surface of the adhesion layer may be the first surface. The method may include, after forming the sacrificial layer and the semiconductor crystal layer and before bonding together the semiconductor crystal layer formation wafer and the transfer-destination wafer, etching the semiconductor crystal layer to expose the sacrificial layer partially and dividing the semiconductor crystal layer into a plurality of divided bodies.

The method may further include, after splitting the transfer-destination wafer from the semiconductor crystal layer formation wafer, bonding together the transfer-destination wafer and a second transfer-destination wafer such that the semiconductor crystal layer side of the transfer-destination wafer and a front surface side of the second transfer-destination wafer face each other; modifying a physical property of the adhesion layer located between the transfer-destination wafer and the semiconductor crystal layer; and separating the second transfer-destination wafer from the transfer-destination wafer with the semiconductor crystal layer remaining on the second transfer-destination wafer. The modifying the physical property includes swelling the organic material layer by immersing the transfer-destination wafer and the second transfer-destination wafer that are bonded together in an organic solvent, or curing the organic material layer by heat or ultraviolet. The method may further include, before splitting the second transfer-destination wafer from the transfer-destination wafer, modifying one or more physical properties selected from a physical property of an interface that dominates adhesive properties between the transfer-destination wafer and the semiconductor crystal layer, a physical property of a layer located between the semiconductor crystal layer and the second transfer-destination wafer, and a physical property of an interface that dominates adhesive properties between the semiconductor crystal layer and the second transfer-destination wafer. The method may further include, after forming the sacrificial layer and the semiconductor crystal layer and before bonding together the semiconductor crystal layer formation wafer and the transfer-destination wafer, forming in the semiconductor crystal layer, an electronic device which includes a portion of the semiconductor crystal layer as an active region.

According to the third aspect related to the present invention, provided is a composite wafer that comprises an inflexible wafer, a single-crystal semiconductor layer, and an organic material layer provided between the inflexible wafer and the semiconductor crystal layer. The semiconductor crystal layer may be GeₓSi₁₋ₓ (0<x≦1). It is preferable that the thickness of the semiconductor crystal layer be equal to or larger than 0.1 nm and smaller than 1 μm. When the semiconductor crystal layer is a single-crystal Ge layer, the full width at half maximum of a diffraction spectrum of the single-crystal Ge layer measured using an X-ray diffraction method may be 40 arcsec or less. An electronic device that has a part of the single-crystal Ge layer as an active region may be formed in the single-crystal Ge layer.

### BRIEF DESCRIPTION OF THE DRAWINGS

FIG. 1 is a sectional view illustrating a step in a method of producing a composite wafer according to a first embodiment.

FIG. 2 is a sectional view illustrating a step in the method of producing a composite wafer according to the first embodiment.

FIG. 3 is a sectional view illustrating a step in the method of producing a composite wafer according to the first embodiment.

FIG. 4 is a sectional view illustrating a step in the method of producing a composite wafer according to the first embodiment.

FIG. 5 is a sectional view illustrating a step in the method of producing a composite wafer according to the first embodiment.

FIG. 6 is a sectional view illustrating a step in a method of producing a composite wafer according to a second embodiment.

FIG. 7 is a sectional view illustrating a step in the method of producing a composite wafer according to the second embodiment.

FIG. 8 is a sectional view illustrating a step in the method of producing a composite wafer according to the second embodiment.

FIG. 9 is a sectional view illustrating a step in a method of producing a composite wafer according to a third embodiment.

FIG. 10 is a sectional view illustrating a step in the method of producing a composite wafer according to the third embodiment.

FIG. 11 is a sectional view illustrating a step in a method of producing a composite wafer according to the third embodiment.

FIG. 12 is a sectional view illustrating a step in a method of producing a composite wafer according to a fourth embodiment.

FIG. 13 is a plan view illustrating a step in the method of producing a composite wafer according to the fourth embodiment.

FIG. 14 is a plan view of a modification example of a pattern of a groove 110 according to the fourth embodiment.

FIG. 15 is a sectional view illustrating a step in a method of producing a composite wafer according to the fourth embodiment.

FIG. 16 is a sectional view illustrating a step in the method of producing a composite wafer according to the fourth embodiment.

FIG. 17 is a sectional view illustrating a step in the method of producing a composite wafer according to the fourth embodiment.

FIG. 18 is a sectional view illustrating a step in the method of producing a composite wafer according to the fourth embodiment.

FIG. 19 is a sectional view illustrating a step in a method of producing a composite wafer according to a fifth embodiment.

FIG. 20 is a sectional view illustrating a step in the method of producing a composite wafer according to the fifth embodiment.

FIG. 21 is a sectional view illustrating a step in the method of producing a composite wafer according to the fifth embodiment.

FIG. 22 is a sectional view illustrating a step in a method of producing a composite wafer according to a sixth embodiment.

FIG. 23 is a sectional view illustrating a step in the method of producing a composite wafer according to the sixth embodiment.

FIG. 24 is a sectional view illustrating a step in the method of producing a composite wafer according to the sixth embodiment.

FIG. 25 is a sectional view illustrating a step in the method of producing a composite wafer according to the sixth embodiment.

FIG. 26 is an SEM image of cross-sections of an AlAs crystal layer and a Ge layer on a GaAs wafer.

FIG. 27 is an SEM image of cross-sections of an AlAs crystal layer and a Ge layer on the GaAs wafer.

FIG. 28 is a graph showing an X-ray rocking curve showing a result measured on the plane (004) of an AlAs crystal layer and a Ge crystal layer formed on a GaAs wafer.

FIG. 29 shows an image of a GeAs wafer with an AlAs crystal layer and a Ge crystal layer formed thereon observed after immersion performed in a 49% HF solution for 5 hours at room temperature.

FIG. 30 shows a Ge crystal layer bonded on a plastic substrate (the left picture) and a GaAs wafer from which a Ge crystal layer has been split away (the right picture).

FIG. 31 is a sectional view showing the process of manufacturing the semiconductor wafer according to Example 1.

FIG. 32 is a sectional view showing the process of manufacturing the semiconductor wafer according to Example 1.

FIG. 33 is an optical microscope image taken by observing a patterned Ge crystal layer which has been transferred onto a silicon wafer via a polyimide film.

FIG. 34 illustrates an example in which the Ge crystal layer of FIG. 33 has been applied to a Hall element.

FIG. 35 shows a sectional view showing the process of manufacturing the semiconductor wafer according to Example 2.

FIG. 36 shows a sectional view showing the process of manufacturing the semiconductor wafer according to Example 2.

FIG. 37 shows a sectional view showing the process of manufacturing the semiconductor wafer according to Example 2.

FIG. 38 shows a sectional view showing the process of manufacturing the semiconductor wafer according to Example 2.

FIG. 39 illustrates an I_{DS}-V_{G} characteristic of a p-channel MOSFET that is one of the elements 302 formed in a Ge crystal layer having been transferred onto a glass substrate.

### DESCRIPTION OF EXEMPLARY EMBODIMENTS

### First Embodiment

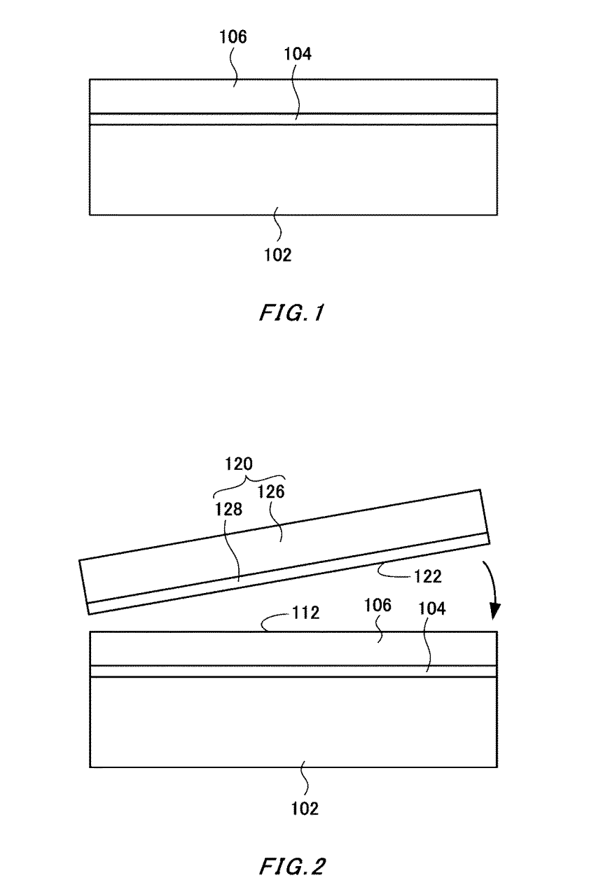

FIGS. 1 to 5 are sectional views illustrating, in order, steps in a method of producing a composite wafer according to a first embodiment. In the method according to the first embodiment, a sacrificial layer 104 and a semiconductor crystal layer 106 are formed on a semiconductor crystal layer formation wafer 102 such that the sacrificial layer 104 is firstly formed and the semiconductor crystal layer 106 is then formed as illustrated in FIG. 1.

The semiconductor crystal layer formation wafer 102 is a substrate for forming a high-quality semiconductor crystal layer 106. Preferable materials for forming the semiconductor crystal layer formation wafer 102 depend on the material, the method, and so on to be used for forming the semiconductor crystal layer 106. The semiconductor crystal layer formation wafer 102 is usually preferably made of a material that is lattice-matched or pseudo-lattice-matched to the semiconductor crystal layer 106 to be formed thereon. For example, when a GaAs layer is formed as the semiconductor crystal layer 106, the semiconductor crystal layer formation wafer 102 is preferably a GaAs single-crystal wafer or may be selected from other single-crystal wafers such as InP, sapphire, Ge or SiC. When the semiconductor crystal layer formation wafer 102 is a GaAs single-crystal wafer, the semiconductor crystal layer 106 may be formed in the plane of the orientation of (100) or (111).

The sacrificial layer 104 is a layer formed for separating the semiconductor crystal layer formation wafer 102 from the semiconductor crystal layer 106. When the sacrificial layer 104 has been removed by etching, the semiconductor crystal layer formation wafer 102 and the semiconductor crystal layer 106 are split from each other. The the etching rate of the sacrificial layer 104 should be larger or preferably several times larger than the etching rates of the semiconductor crystal layer formation wafer 102 and the semiconductor crystal layer 106 because the semiconductor crystal layer formation wafer 102 and the semiconductor crystal layer 106 need to remain intact even after the sacrificial layer 104. When a GaAs single-crystal wafer is chosen as the semiconductor crystal layer formation wafer 102 and a GaAs layer is chosen as the semiconductor crystal layer 106, the sacrificial layer 104 is preferably an AlAs layer, or it is preferably selected from among an InAlAs layer, an InGaP layer, an InAlP layer, an InGaAlP layer, or an AlSb layer. When the thickness of the sacrificial layer 104 increases, the crystallinity of the semiconductor crystal layer 106 tends to deteriorate, and therefore the thickness of the sacrificial layer 104 is preferably as thin as possible as long as the layer can serve as a sacrificial layer. The thickness of the sacrificial layer 104 can be selected in a range from 0.1 nm to 10 μm. The sacrificial layer 104 may be thinner than the semiconductor crystal layer formation wafer 102 and the semiconductor crystal layer 106.

The sacrificial layer 104 can be formed by an epitaxial growth method, a chemical vapor deposition (CVD) method, a sputtering method, or an atomic layer deposition (ALD) method. As the epitaxial growth method, a Metal Organic Chemical Vapor Deposition (MOCVD) method and a Molecular Beam Epitaxy (MBE) method can be used. When the sacrificial layer 104 is formed by a MOCVD method, TMGa (trimethyl-gallium), TMA (trimethyl-aluminum), TMIn (trimethyl-indium), AsH₃ (arsine), PH₃ (phosphine) or the like can be used as a source gas. Hydrogen can be used for a carrier gas. Compounds in which a part of hydrogen atoms of the above-mentioned source gas have been substituted by chlorine atoms or hydrocarbon groups can also be used. The reaction temperature can be selected in a range from 300° C. to 900° C., more preferably in a range from 400° C. to 800° C. The thickness of the sacrificial layer 104 can be controlled by adequately controlling the amount of the source gas supply and the reaction time.

The semiconductor crystal layer 106 is a transfer-target layer, which is to be transferred onto a transfer-destination wafer, which is hereunder described. The semiconductor crystal layer 106 is used as an active layer or the like for a semiconductor device. High crystallinity of the semiconductor crystal layer 106 is secured successfully by forming the semiconductor crystal layer 106 on the semiconductor crystal layer formation wafer 102 by an epitaxial growth method or the like. On the other hand, since the semiconductor crystal layer 106 is transferred onto a transfer-destination wafer, the semiconductor crystal layer 106 can be transferred onto an arbitrary transfer-destination wafer without regardless of, for example, lattice matching to the transfer-destination wafer.

Examples of the semiconductor crystal layer 106 include a crystal layer of a Group III-V compound semiconductor, a crystal layer of a Group IV semiconductor or a Group II-VI compound semiconductor, and a stack of such crystal layers. Examples of the Group III-V compound semiconductor include GaAs, InₓGa₁₋ₓAs (0<x<1), InP, or GaSb. Examples of the Group IV semiconductor include Ge or GeₓSi₁₋ₓ (0<x<1). Examples of the Group II-VI compound semiconductor include ZnO, ZnSe, ZnTe, CdS, CdSe, or CdTe. When the Group IV semiconductor is GeₓSi₁₋ₓ, the compositional ratio “x” of Ge in GeSil-x is preferably 0.9 or more. By setting the compositional ratio of Ge to 0.9 or more, it is possible to obtain a semiconductor property like that of Ge. Use of the above-mentioned crystal layer or stack as the semiconductor crystal layer 106 makes it possible to use the semiconductor crystal layer 106 as an active layer in a high-mobility field effect transistor, in particular, a high-mobility complementary field effect transistor.

The thickness of the semiconductor crystal layer 106 can be chosen in a range of from 0.1 nm to 500 μm. The thickness of the semiconductor crystal layer 106 is preferably not less than 0.1 nm and not larger than 1 μm. By forming the semiconductor crystal layer 106 in a thickness of 1 μm or less, the layer can be used for a composite wafer suitable for the manufacture of a high-performance transistor such as an ultra-thin MISFET.

The semiconductor crystal layer 106 can be formed by an epitaxial growth method or an ALD method. As the epitaxial growth method, a MOCVD method or a MBE method can be used. When the semiconductor crystal layer 106 made of a Group III-V compound semiconductor is formed by a MOCVD method, TMGa (trimethyl-gallium), TMA (trimethyl-aluminum), TMIn (trimethyl-indium), AsH₃ (arsine), PH₃ (phosphine) or the like can be used as a source gas. When the semiconductor crystal layer 106 made of a Group IV compound semiconductor is formed by a MOCVD method, GeH₄ (germane), SiH₄ (silane), Si₂H₆ (disilane) or the like can be used as a source gas. Hydrogen can be used for a carrier gas. Compounds in which a part of hydrogen atoms of the above-mentioned source gas have been substituted by chlorine atoms or hydrocarbon groups can also be used. The reaction temperature can be selected in a range from 300° C. to 900° C., more preferably in a range from 400° C. to 800° C. The thickness of the semiconductor crystal layer 106 can be controlled by adequately controlling the amount of the source gas supply and the reaction time.

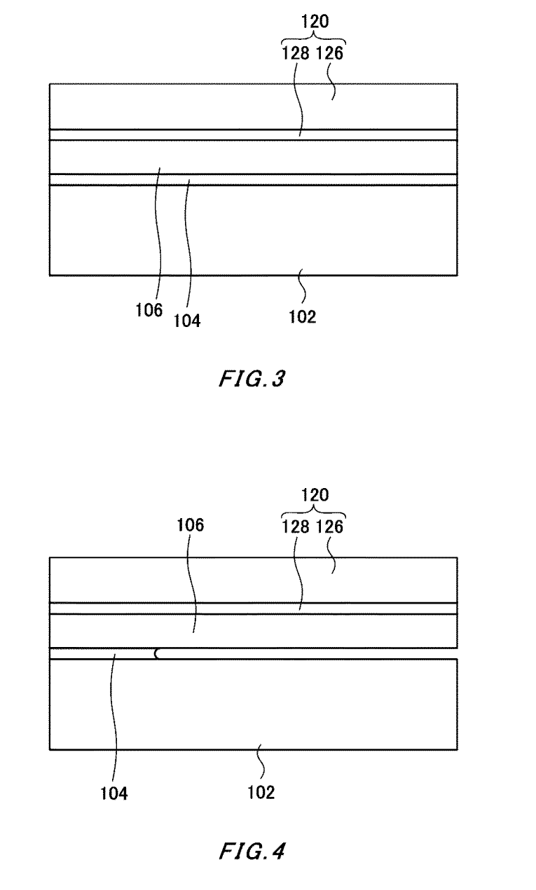

Referring to FIG. 2, the front surface of the transfer-destination wafer 120 is directed to face the semiconductor crystal layer 106 disposed on the semiconductor crystal layer formation wafer 102, and as illustrated in FIG. 3, the transfer-destination wafer 120 and the semiconductor crystal layer formation wafer 102 are then bonded together.

The transfer-destination wafer 120 comprises an inflexible wafer 126 and an organic material layer 128. The inflexible wafer 126 is the wafer onto which the semiconductor crystal layer 106 is to be transferred. The inflexible wafer 126 may be either a target wafer on which an electric device using the semiconductor crystal layer 106 as an active layer is to be finally arranged or a temporal wafer on which the semiconductor crystal layer 106 is to be placed temporally before the semiconductor crystal layer 106 is transferred to other target wafer. The inflexible wafer 126 may be made of either an organic material or an inorganic material. Examples of the inflexible wafer 126 include a silicon wafer, a SOI wafer, a glass substrate, a sapphire wafer, a SiC wafer, and an AN wafer. Alternatively, the inflexible wafer 126 may be an insulator wafer such as a ceramics wafer and a plastic wafer, or a conductive wafer such as a metal wafer. When a silicon wafer or an SOI wafer is used as the inflexible wafer 126, manufacturing apparatuses used in conventional silicon processes can be utilized, and it is possible to enhance efficiency of research, development, and production by utilizing knowledge about conventional silicon processes. Since the inflexible wafer 126 is a rigid wafer which cannot be easily bent, the semiconductor crystal layer 106 that is to be transferred can be protected from mechanical vibrations and the like, and accordingly it is possible to maintain a high crystal quality of the semiconductor crystal layer 106.

The organic material layer 128 can be used as an adhesion layer that increases the adhesiveness between the semiconductor crystal layer 106 and the inflexible wafer 126. Even when the surface of semiconductor crystal layer 106 has irregularities, minor irregularities are absorbed by the organic material layer 128 and the semiconductor crystal layer 106 can be bonded to the inflexible wafer 126 well. Examples of the organic material layer 128 include a polyimide film and a resist film. In such cases, the organic material layer 128 can be formed by an application method such as spin coating. The thickness of the organic material layer 128 may be in a range between from 0.1 nm to 100 μm.

The surface 112 of the semiconductor crystal layer 106 disposed on the semiconductor crystal layer formation wafer 102 is an example of a “ first surface” which is to be in contact with the transfer-destination wafer 120 or a layer formed on the transfer-destination wafer 120 when the semiconductor crystal layer formation wafer 102 and the transfer-destination wafer 120 are bonded together. When another layer is formed on the semiconductor crystal layer 106, the “ first surface” referrers to the surface of the top layer. The surface 122 of the organic material layer 128 formed on the transfer-destination wafer 120 is an example of a “ second surface” which is to be in contact with the surface 112 of the semiconductor crystal layer 106 when the semiconductor crystal layer formation wafer 102 and the transfer-destination wafer 120 are bonded together. The transfer-destination wafer 120 and the semiconductor crystal layer formation wafer 102 are bonded together such that the surface 112 of the semiconductor crystal layer 106, which is the first surface, and the surface 122 of the organic material layer 128, which is the second surface, are jointed.

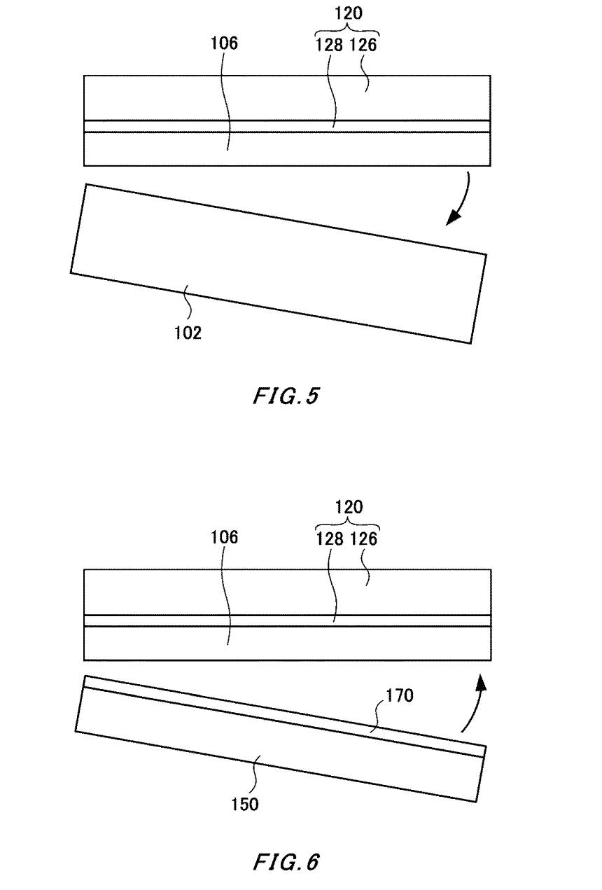

Referring next to FIG. 4, the whole or a part (preferably the whole) of the semiconductor crystal layer formation wafer 102 and the transfer-destination wafer 120 are immersed in an etchant to etch the sacrificial layer 104. Through the etching of the sacrificial layer 104, the transfer-destination wafer 120 and the semiconductor crystal layer formation wafer 102 are split from each other with the semiconductor crystal layer 106 remaining on the transfer-destination wafer 120 as illustrated in FIG. 5.

The sacrificial layer 104 can be selectively etched. Here, “selectively etched” also means that substantially only the sacrificial layer 104 is etched “selectively” when in addition to the sacrificial layer 104, other components such as the semiconductor crystal layer 106 is also immersed in the etchant and etched together with the layer 104 if the material of the etchant or other conditions are chosen so that the etching rate of the sacrificial layer 104 will be higher than those of the other components. When the sacrificial layer 104 is an AlAs layer, examples of the etchant 142 include HCl, HF, phosphoric acid, citric acid, hydrogen peroxide solution, ammonia, aqueous sodium hydroxide and water. It is preferable to control the temperature of the etchant within a range of from 10° C. to 90° C. during etching. The etching time can be adequately controlled within a range from one minute to 200 hours.

The sacrificial layer 104 can be etched while ultrasonic wave is applied to the etchant. By applying the ultrasonic wave, it is possible to increase the etching rate. Moreover, ultraviolet ray may be irradiated or the etchant may be stirred.

As described above, when the sacrificial layer 104 has been removed by etching, the transfer-destination wafer 120 and the semiconductor crystal layer formation wafer 102 are split from each other with the semiconductor crystal layer 106 remaining on the transfer-destination wafer 120 as shown in FIG. 5. In the above-described manner, the semiconductor crystal layer 106 is transferred onto the transfer-destination wafer 120, so that a composite wafer that has the semiconductor crystal layer 106 on the transfer-destination wafer 120 is produced.

According to the method of producing a composite wafer of the first embodiment, the semiconductor crystal layer 106 can be transferred onto the transfer-destination wafer 120 that includes the organic material layer 128 on the inflexible wafer 126.

### Second Embodiment

FIGS. 6 through 8 illustrate sectional views illustrating, in order, steps in the method of producing a composite wafer according to the second embodiment. In the second embodiment, a composite wafer that includes the semiconductor crystal layer 106 on the transfer-destination wafer 120 that has the organic material layer 128 on the inflexible wafer 126 and produced according to the method of the first embodiment is used. In the second embodiment is described a method of producing a composite wafer in which method the semiconductor crystal layer 106 disposed on the transfer-destination wafer 120 is further transferred onto a second transfer-destination wafer 150 to afford the composite wafer comprising the second transfer-destination wafer 150 and the semiconductor crystal layer 106 disposed thereon.

Referring to FIG. 6, the second transfer-destination wafer 150 that has an adhesion layer 170 and the transfer-destination wafer 120 that has the semiconductor crystal layer 106 are bonded together. Bonding is performed such that the semiconductor crystal layer 106 of the transfer-destination wafer 120 faces the adhesion layer 170 of the second transfer-destination wafer 150.

The second transfer-destination wafer 150 is a destination wafer onto which the semiconductor crystal layer 106 is to be transferred. The second transfer-destination wafer 150 may be either a final target wafer or a temporal wafer. The second transfer-destination wafer 150 may be made of either an organic material or an inorganic material. Examples of the second transfer-destination wafer 150 include a silicon wafer, a Silicon on Insulator (SOI) wafer, a glass substrate, a sapphire wafer, a SiC wafer, and an AlN wafer. Alternatively, the second transfer-destination wafer 150 may be an insulator wafer such as a ceramics wafer and a plastic wafer, or a conductive wafer such as a metal wafer. When a silicon wafer or an SOI wafer is used as the second transfer-destination wafer 150, manufacturing apparatuses used in conventional silicon processes can be utilized, and it is possible to enhance efficiency of research, development, and production by utilizing knowledge about conventional silicon processes. Since the second transfer-destination wafer 150 is a hard wafer which cannot be easily bent such as a silicon wafer, the semiconductor crystal layer 106 that is to be transferred can be protected from mechanical vibrations and the like, and accordingly it is possible to maintain a high crystal quality of the semiconductor crystal layer 106.

The adhesion layer 170 is provided for increasing adhesiveness between the semiconductor crystal layer 106 and the second transfer-destination wafer 150, and it may be made of either an organic material or an inorganic material. The adhesion layer 170 is not necessarily provided. When the adhesion layer 170 is made of an organic material, even if the surface of the semiconductor crystal layer 106 has irregularities, minor irregularities can be absorbed by the adhesion layer 170 and the semiconductor crystal layer 106 can be bonded to the second transfer-destination wafer 150 well. When the adhesion layer 170 is made of an inorganic material, it can be stable even if it is subjected to a high-temperature process of several hundreds degrees Celsius during a later process. When the adhesion layer 170 is made of an inorganic material, it can be utilized for an insulating layer or the like in a later-fabricated device and it may be possible to facilitate a manufacturing process.

When the adhesion layer 170 is made of an organic material, examples of the adhesion layer 170 include a polyimide film, a resist film and the like. In such cases, the adhesion layer 170 can be formed by an application method such as spin coating. When the adhesion layer 170 is made of an inorganic material, examples of the adhesion layer 170 include a single layer or stack of two or more layers made of at least one selected from among Al₂O₃, AlN, Ta₂O₅, ZrO₂, HfO₂, SiOₓ (for example, SiO₂), SiNₓ (for example, Si₃N₄), and SiOₓN_{y}. In this case, the adhesion layer 170 can be formed by an ALD method, a thermal oxide method, a deposition method, a CVD method, or a spattering method. The thickness of the adhesion layer 170 may be in a range of from 0.1 nm to 100 μm.

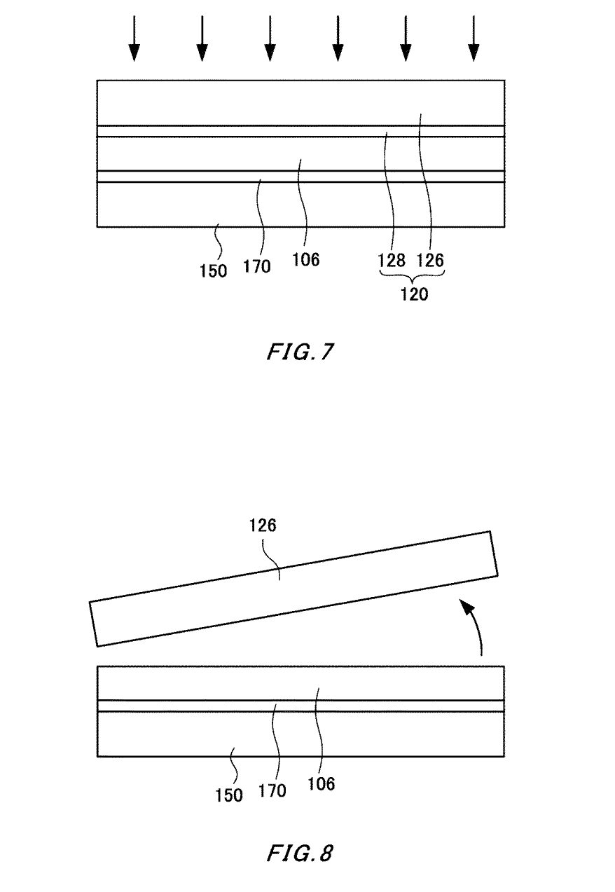

Referring to FIG. 7, a physical property of the organic material layer 128 that dominates the adhesiveness between the transfer-destination wafer 120 and the semiconductor crystal layer 106 are changed so as to decrease the adhesiveness. The physical property of the organic material layer 128 can be changed by, for example, swelling the organic material layer 128 with an organic solvent. By swelling the organic material layer 128, the adhesiveness between the transfer-destination wafer 120 (the inflexible wafer 126) and the semiconductor crystal layer 106 is decreased.

When the adhesiveness between the transfer-destination wafer 120 (the inflexible wafer 126) and the semiconductor crystal layer 106 is decreased as described above, the transfer-destination wafer 120 (the inflexible wafer 126) and the second transfer-destination wafer 150 are split from each other with the semiconductor crystal layer 106 remaining on the second transfer-destination wafer 150 as shown in FIG. 8. In this manner, the semiconductor crystal layer 106 is transferred onto the second transfer-destination wafer 150, so that a composite wafer that includes the semiconductor crystal layer 106 disposed on the second transfer-destination wafer 150 is produced.

According to the method of producing a composite wafer of the second embodiment, physical property modification is conducted to decrease the adhesiveness between the transfer-destination wafer 120 (the inflexible wafer 126) and the semiconductor crystal layer 106 after the transfer-destination wafer 120 and the second transfer-destination wafer 150 have been bonded, and therefore the adhesiveness can be controlled depending on transfer steps and consequently the transfer process which includes more than one step can be stably performed.

Although the case that the organic material layer 128 is provided as the adhesion layer between the transfer-destination wafer 120 (the inflexible wafer 126) and the semiconductor crystal layer 106 has been described in the above embodiment, physical properties of the interface that is dominant in the adhesiveness between the transfer-destination wafer 120 and the semiconductor crystal layer 106 may be modified. A physical property of the interface can be modified by, for example, swelling the transfer-destination wafer 120 with an organic solvent when the transfer-destination wafer 120 is made of an organic material. Although the adhesiveness between the transfer-destination wafer 120 and the semiconductor crystal layer 106 is decreased in the above-described second embodiment, a physical property of the interface that dominates the adhesiveness of the semiconductor crystal layer 106 and the second transfer-destination wafer 150, in other words, a physical property of the joint interface between the semiconductor crystal layer 106 and the second transfer-destination wafer 150 can be modified so as to increase the adhesiveness. When an adhesion layer is provided between the semiconductor crystal layer 106 and the second transfer-destination wafer 150, a physical property of the adhesion layer can be modified. The physical property modification may be modification in the adhesiveness at the interface.

Examples of the physical property modification include activation of the interface, and examples of the physical property modification to decrease the adhesiveness include swelling of the organic material with an organic solvent, hardening of the organic material with heat or ultraviolet ray, and so on.

### Third Embodiment

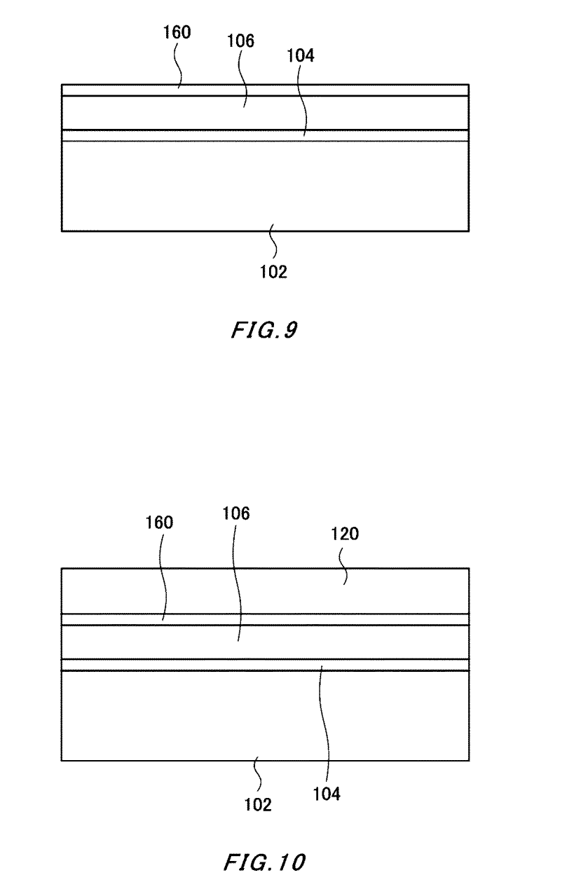

FIGS. 9 through 11 illustrate sectional views illustrating, in order, steps in a method of producing a composite wafer according to a third embodiment. In the third embodiment, the adhesion layer 160 is formed between the semiconductor crystal layer 106 and transfer-destination wafer 120. Since the producing method of the third embodiment has many common features with the producing method of the first embodiment, different features are mainly hereunder described and descriptions of the common features will be omitted.

Referring to FIG. 9, the adhesion layer 160 is further formed on the semiconductor crystal layer 106 after the sacrificial layer 104 and semiconductor crystal layer 106 have been formed on the semiconductor crystal layer formation wafer 102. The adhesion layer 160 is a layer for increasing the adhesiveness between the semiconductor crystal layer 106 and the transfer-destination wafer 120 and is made of an organic material. Because the adhesion layer 160 is made of an organic material, even if the surface of the semiconductor crystal layer 106 has irregularities, the minor irregularities are absorbed by the adhesion layer 160 and the semiconductor crystal layer 106 can be bonded to the transfer-destination wafer 120 well. Therefore, the level of the flatness required for the semiconductor crystal layer 106 can be lowered.

Examples of the adhesion layer 160 include a polyimide film and a resist film. In such cases, the adhesion layer 160 can be formed by an application method such as spin coating. The thickness of the adhesion layer 160 may be in a range of 0.1 nm to 100 μm. It is preferable that the transfer-destination wafer 120 be a similar wafer as the inflexible wafer 126 which has been described in the first embodiment. Even when the inflexible wafer is used as the transfer-destination wafer 120, since a layer made of an organic material is used as the adhesion layer 160 according to the third embodiment, it is possible to bond the semiconductor crystal layer formation wafer 102 and the transfer-destination wafer 120 together in the same manner as the first embodiment.

Referring to FIG. 10, the front surface of the transfer-destination wafer 120 and the semiconductor crystal layer 106 of the semiconductor crystal layer formation wafer 102 face each other, and the transfer-destination wafer 120 and the semiconductor crystal layer formation wafer 102 are bonded together. Here, the surface of the adhesion layer 160 is an example of a “first surface” which is to be in contact with the transfer-destination wafer 120 or a layer formed on the transfer-destination wafer 120 when the transfer-destination wafer 120 and the semiconductor crystal layer formation wafer 102 are bonded together. The surface of the transfer-destination wafer 120 is an example of a “second surface” which is to be in contact with the first surface. The transfer-destination wafer 120 and the semiconductor crystal layer formation wafer 102 are bonded together such that the surface of the adhesion layer 160, which is the first surface, and the surface of the transfer-destination wafer 120, which is the second surface, are jointed. Bonding is performed in the same manner as the first embodiment.

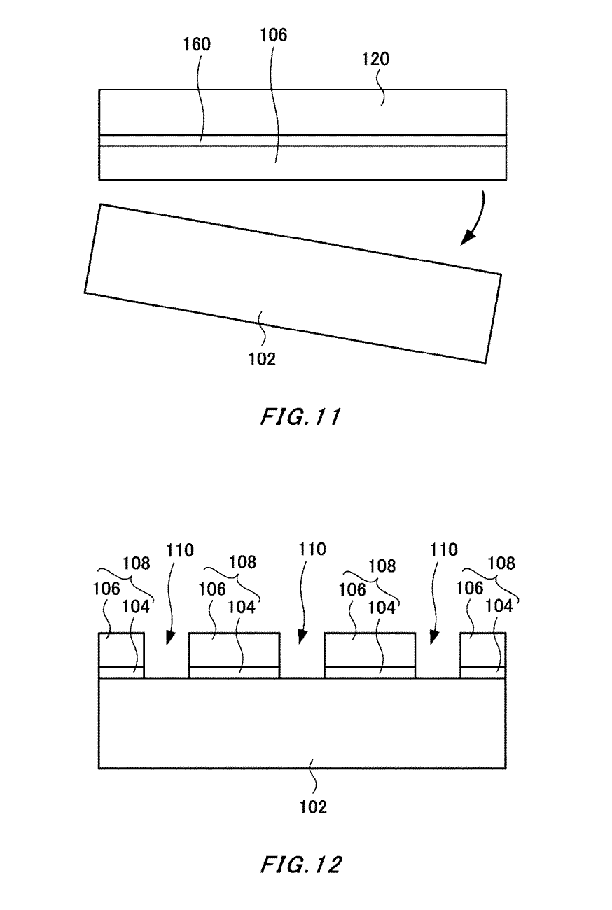

The sacrificial layer 104 is then etched, and the transfer-destination wafer 120 and the semiconductor crystal layer formation wafer 102 are split from each other with the adhesion layer 160 and the semiconductor crystal layer 106 remaining on the transfer-destination wafer 120 as illustrated in FIG. 11. Splitting is performed in the same manner as the first embodiment. In the above-described manner, the adhesion layer 160 and the semiconductor crystal layer 106 are transferred onto the transfer-destination wafer 120, so that a composite wafer that has the adhesion layer 160 and the semiconductor crystal layer 106 disposed on the transfer-destination wafer 120 is produced.

Since the adhesion layer 160 is provided according to the method of producing a composite wafer of the third embodiment, it is possible to secure adhesion between the transfer-destination wafer 120 and the semiconductor crystal layer 106. Moreover, the surface irregularities of the semiconductor crystal layer 106 are absorbed by the organic adhesion layer 160 and therefore the level of the flatness required for the semiconductor crystal layer 106 can be lowered.

Furthermore, the third embodiment also has the same advantage as the second embodiment, which is that the semiconductor crystal layer 106 on the transfer-destination wafer 120 can be further transferred onto the second transfer-destination wafer 150 by using the composite wafer of the third embodiment. In this case, the adhesion layer 160 can be used as a sacrificial layer to be used for splitting the semiconductor crystal layer 106 from the transfer-destination wafer 120 after the semiconductor crystal layer 106 has been transferred onto the second transfer-destination wafer 150.

Moreover, after the sacrificial layer 104 and the semiconductor crystal layer 106 have been formed on the semiconductor crystal layer formation wafer 102 and before the semiconductor crystal layer formation wafer 102 and the transfer-destination wafer 120 are bonded together, an electronic device that utilizes a part of the semiconductor crystal layer 106 as an active region may be formed in the semiconductor crystal layer 106. In this case, the semiconductor crystal layer 106 is transferred while having the electronic device therein. According to the above-described method, the front surface and the back surface are reversed at every time when the semiconductor crystal layer 106 is transferred, so that an electronic device can be formed on both sides of the semiconductor crystal layer 106.

### Fourth Embodiment

FIGS. 12 through 18 are sectional views or plan views illustrating, in order, steps in a method of producing a composite wafer according to a fourth embodiment. In the method according to the fourth embodiment, the sacrificial layer 104 and the semiconductor crystal layer 106 are formed on the semiconductor crystal layer formation wafer 102 such that the sacrificial layer 104 is firstly formed and the semiconductor crystal layer 106 is then formed as illustrated in FIG. 1. Configurations of the semiconductor crystal layer formation wafer 102, the sacrificial layer 104, and the semiconductor crystal layer 106 are same as those in the first embodiment.

Referring to FIG. 12, the semiconductor crystal layer 106 is etched so as to expose a part of the sacrificial layer 104, and the semiconductor crystal layer 106 is divided into a plurality of divided bodies 108. Grooves 110 are formed between two adjacent divided bodies 108 after the etching. Here “to expose a part of the sacrificial layer 104” also means the following cases in which the sacrificial layer 104 is substantially completely exposed in an etching region where the groove 110 is formed. There is a case where the sacrificial layer 104 is completely etched on the bottom of the groove 110, the semiconductor crystal layer formation wafer 102 is exposed at the bottom of the grooves 110, and the sectional surface of the sacrificial layer 104 is exposed as a part of a lateral surface of the groove 110. There is another case where the sacrificial layer 104 is half etched in the region where the groove 110 is formed and the sacrificial layer 104 is exposed at the bottom of the groove 110. There is still another case where the semiconductor crystal layer 106 remains in a portion of the bottom of the groove 110 and a part of the sacrificial layer 104 is exposed at the bottom of the groove 110. There is still another case where a very thin semiconductor crystal layer 106 remains on the whole bottom surface of the groove 110, but the thickness of the semiconductor crystal layer 106 is so thin that an etchant can penetrate therethough and therefore it can be described as the sacrificial layer 104 is substantially completely exposed.

Either a dry etching method or a wet etching method can be used for the etching to form the grooves 110. In the case of dry etching, a halogen gas such as SF₆ or CH₄₋ₓFₓ (x is an integer of from 1 to 4) can be used as an etching gas. In the case of wet etching, a solution of HCl, HF, phosphoric acid, citric acid, hydrogen peroxide solution, ammonia, or sodium hydroxide can be used as an etchant. A mask for etching can be made of an organic or inorganic material that has an appropriate etching selectivity, and any pattern of the grooves 110 can be formed by patterning the mask. The semiconductor crystal layer formation wafer 102 can be utilized as an etching stopper during the etching for forming the grooves 110. However, considering that the semiconductor crystal layer formation wafer 102 is reused, it is preferable that etching be stopped on the surface or halfway of the sacrificial layer 104.

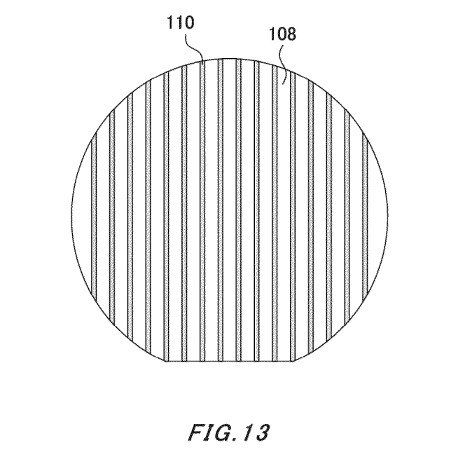

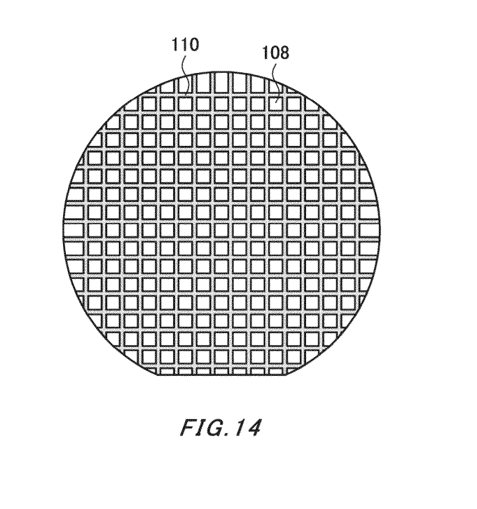

Since the grooves 110 are provided, an etchant is supplied through the grooves 110 when the sacrificial layer 104 is etched, and when many grooves 110 are formed, the width of the sacrificial layer 104 needs to be etched can be reduced, and it is possible to shorten the time which is needed for the removal of the sacrificial layer 104. FIG. 13 is a plan view of the semiconductor crystal layer formation wafer 102 viewed from the top showing a pattern of the grooves 110. The pattern of the grooves 110 illustrated in FIG. 13 is a stripe pattern in which a plurality of linear grooves 110 are arranged in parallel. Because the time required for removal of the sacrificial layer 104 can be shorten, a gap between two adjacent grooves 110 is preferably made as small as possible provided that it satisfies the size requirement of the semiconductor crystal layer 106 (the divided body 108). The width of the groove 110 is preferably set to from 0.00001 to 1 times of the distance to an adjacent groove 110 when the grooves are arranged in parallel to each other. The distance between two adjacent grooves 110 refers to a shortest distance between two facing sides of the adjacent grooves. Alternatively, the pattern of the grooves 110 can be a lattice pattern in which two stripes intersect at a right angle as illustrated in FIG. 14. Considering reduction of time required for the removal of the sacrificial layer 104, the lattice pattern illustrated in FIG. 14 is preferable. When the pattern of the grooves 110 is a lattice pattern, two stripes do not necessarily intersect at a right angle but any angle except for 0 degree and 180 degrees. The lattice pattern may include a partial lattice pattern. The plan pattern of the grooves 110 may be of any configuration. In other words, a planar shape of the semiconductor crystal layer 106 defined by the grooves 110 may be any shape including a stripe, rectangle and quadrate.

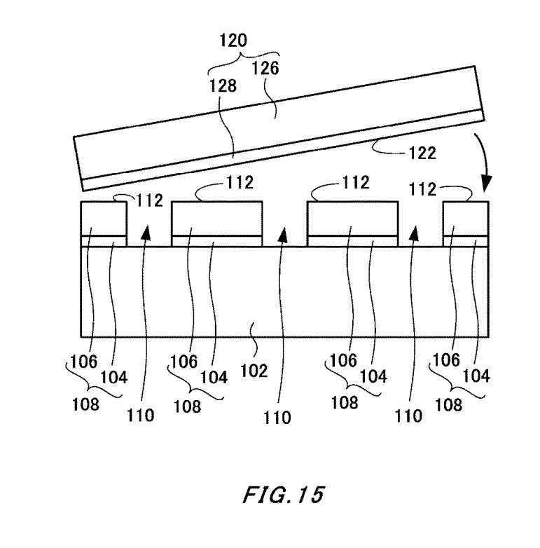

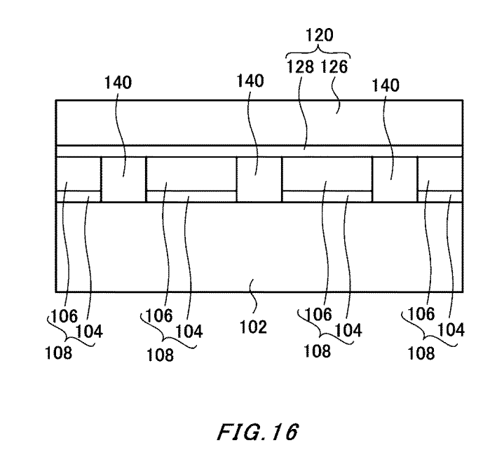

Next, as illustrated in FIG. 15, the front surface side of the transfer-destination wafer 120 and the semiconductor crystal layer 106 side of the semiconductor crystal layer formation wafer 102 face each other, and then the transfer-destination wafer 120 and the semiconductor crystal layer formation wafer 102 are bonded together as illustrated in FIG. 16. When these are bonded together, a hollow section 140 is defined by the inner walls of the groove 110 and the surface of the organic material layer 128.

The transfer-destination wafer 120 comprises the inflexible wafer 126 and the organic material layer 128. The inflexible wafer 126 and the organic material layer 128 are same as those in the first embodiment.

The surfaces 112 of the semiconductor crystal layer 106 other than the grooves 110 on the semiconductor crystal layer formation wafer 102 are an example of a “ first surface” which is the surface of a layer formed on the semiconductor crystal layer formation wafer 102 and is to be in contact with the transfer-destination wafer 120 and a layer formed on the transfer-destination wafer 120. The surface 122 of the organic material layer 128 facing the surface 112 is an example of a “second surface” which is the surface of the transfer-destination wafer 120 or a layer formed on the transfer-destination wafer 120 and is to be in contact with the surface 112. The transfer-destination wafer 120 and the semiconductor crystal layer formation wafer 102 are bonded together such that the surface 112 of the semiconductor crystal layer 106, which is the first surface, and the surface 122 of the organic material layer 128, which is the second surface, are jointed together.

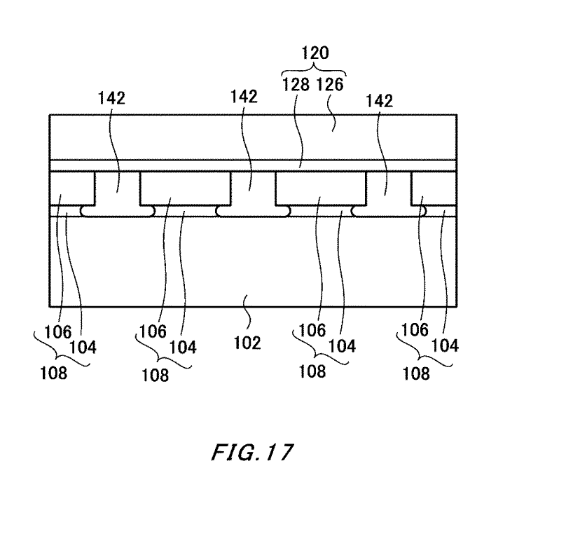

Referring next to FIG. 17, the etchant 142 is supplied to the hollow section 140. Examples of the method of supplying the etchant 142 to the hollow section 140 include a method utilizing capillarity to supply the etchant 142 to the hollow section 140, a method to force the etchant 142 to be supplied into the hollow section 140 by immersing one end of the hollow section 140 in the etchant 142 and suctioning the etchant 142 from the other end of the hollow section viewed from above the semiconductor crystal layer formation wafer 102 as illustrated in FIG. 13, and another method to force the etchant 142 to be supplied into the hollow section 140 when one end of the hollow section 140 is open and the other end is closed by placing the transfer-destination wafer 120 and the semiconductor crystal layer formation wafer 102 under a reduced pressure, immersing the open end of the hollow section 140 in the etchant 142, and then placing the transfer-destination wafer 120 and the semiconductor crystal layer formation wafer 102 under the atmospheric pressure. When one end of the hollow section 140 is open and the other end is closed, the plurality of divided bodies 108 may not necessarily be divided. For example, when one end of each of the grooves 110 arranged in a stripe pattern as illustrated in FIG. 13 reaches the edge of the semiconductor crystal layer formation wafer 102 whereas the other end does not reach the edge of the semiconductor crystal layer formation wafer 102, the divided bodies 108 are connected to each other through the edge of the semiconductor crystal layer formation wafer 102 and they are not completely separated from each other. In this specification, “the semiconductor crystal layer 106 is divided into a plurality of divided bodies 108” encompasses the above-mentioned state in which a plurality of divided bodies 108 are connected to each other through the edge of the semiconductor crystal layer formation wafer 102 and are not completely separated.

Before the transfer-destination wafer 120 and the semiconductor crystal layer formation wafer 102 are bonded together, the inside of the groove 110 can be made hydrophilic. In this example, the inner walls of the groove 110 are made hydorophilic. Here, the inner walls refer to surfaces exposed inside the groove 110 such as a lateral wall, a bottom surface and the like of the groove 110. Moreover, inner walls of the hollow section 140 can be made hydrophilic. Here, the inner walls of the hollow section 140 refer to surfaces exposed inside the hollow section 140 such as a lateral wall, a bottom surface, and an upper surface. Making the inside of the groove 110 or the hollow section 140 hydrophilicimproves to supply an etchant smoothly to the hollow section 140. Examples of a method of making the inside of the groove 110 hydrophilic includes a method in which the inside of the groove 110 is exposed to an HCl gas, a method in which a hydrophilic ion (for example, a hydrogen ion) is injected in the inside of the groove 110, and so on.

The sacrificial layer 104 is etched using the etchant 142 supplied in the hollow section 140. It is preferable that etching of the sacrificial layer 104 is selective etching. The meaning of selective etching has been described above. When the sacrificial layer 104 is an AlAs layer, examples of the etchant 142 include HCl, HF, phosphoric acid, citric acid, hydrogen peroxide solution, ammonia, aqueous sodium hydroxide and water. The temperature during the etching is preferably controlled within a range of 10° C. to 90° C. The etching time can be adequately chosen within a range from one minute to 200 hours.

The sacrificial layer 104 can be etched while ultrasonic wave is applied to the hollow section 140 filled with the etchant 142. By applying the ultrasonic wave, it is possible to increase the etching rate. Moreover, ultraviolet rays may be irradiated or the etchant may be stirred.

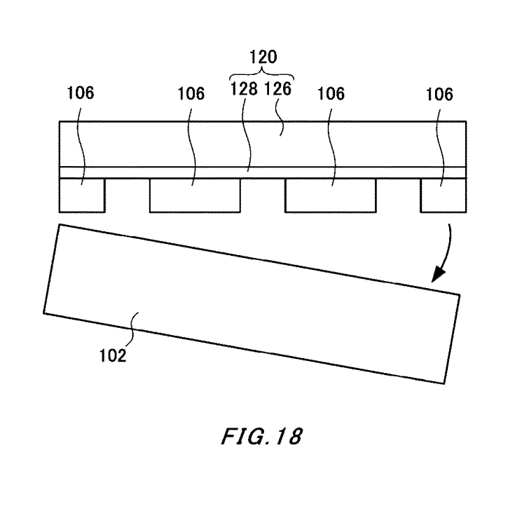

As described above, when the sacrificial layer 104 has been removed by etching, the transfer-destination wafer 120 and the semiconductor crystal layer formation wafer 102 are split from each other with the semiconductor crystal layer 106 remaining on the transfer-destination wafer 120 as shown in FIG. 18. In the above-described manner, the semiconductor crystal layer 106 is transferred onto the transfer-destination wafer 120, and a composite wafer that has the semiconductor crystal layer 106 on the transfer-destination wafer 120 is produced.

According to the method of producing a composite wafer of the fourth embodiment, the semiconductor crystal layer 106 can be transferred onto the transfer-destination wafer 120 that comprises the organic material layer 128 on the inflexible wafer 126. Moreover, according to the method of producing a composite wafer of the fourth embodiment, the grooves 110 are formed in the semiconductor crystal layer formation wafer 102 and the hollow sections 140 are formed when the semiconductor crystal layer formation wafer 102 and the transfer-destination wafer 120 are bonded together, an etchant is supplied to the sacrificial layer 104 via the hollow section 140. Therefore even when the transfer-destination wafer 120 has the inflexible wafer 126, the sacrificial layer 104 is quickly etched and removed. As a result, the transfer-destination wafer 120 and the semiconductor crystal layer formation wafer 102 are promptly split and it is possible to improve the production throughput.

### Fifth Embodiment

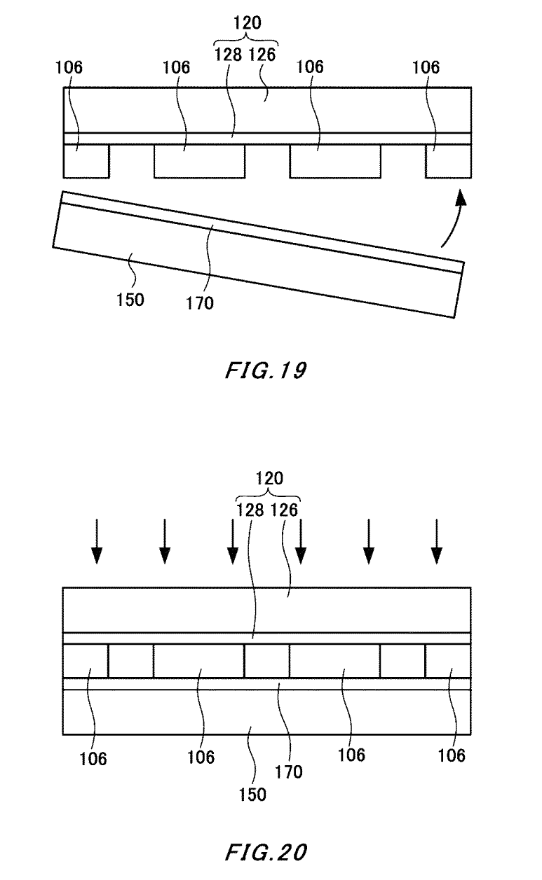

FIGS. 19 through 21 are sectional views illustrating, in order, steps in a method of producing a composite wafer according to a fifth embodiment. In the fifth embodiment, a composite wafer that comprises the semiconductor crystal layer 106 on the transfer-destination wafer 120 which has been produced according to the method of the fourth embodiment is used, and the semiconductor crystal layer 106 disposed on the transfer-destination wafer 120 is further transferred onto the second transfer-destination wafer 150. In this way, a composite wafer that comprises the semiconductor crystal layer 106 disposed on the second transfer-destination wafer 150 is produced.

Referring to FIG. 19, the second transfer-destination wafer 150 that has the adhesion layer 170 and the transfer-destination wafer 120 that has the semiconductor crystal layer 106 are bonded together. Bonding is performed such that the semiconductor crystal layer 106 of the transfer-destination wafer 120 faces the adhesion layer 170 of the second transfer-destination wafer 150. The second transfer-destination wafer 150 and the adhesion layer 170 are same as those in the second embodiment.

Referring to FIG. 20, a physical property of the organic material layer 128 that dominates the adhesiveness between the transfer-destination wafer 120 and the semiconductor crystal layer 106 is changed so as to decrease the adhesiveness. The physical property of the organic material layer 128 can be changed by, for example, swelling the organic material layer 128 with an organic solvent. By swelling the organic material layer 128, the adhesiveness between the transfer-destination wafer 120 (the inflexible wafer 126) and the semiconductor crystal layer 106 is decreased.

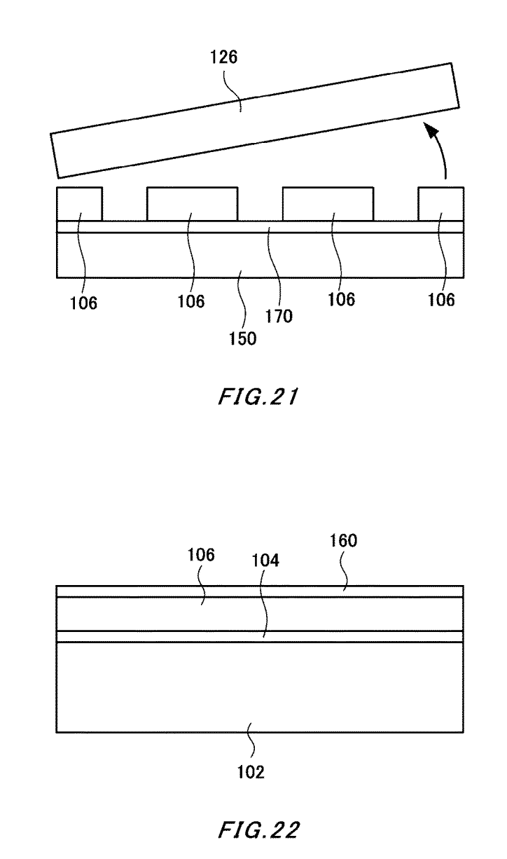

When the adhesiveness between the transfer-destination wafer 120 (the inflexible wafer 126) and the semiconductor crystal layer 106 is decreased as described above, the transfer-destination wafer 120 (the inflexible wafer 126) and the second transfer-destination wafer 150 can be split from each other with the semiconductor crystal layer 106 remaining on the second transfer-destination wafer 150 as shown in FIG. 21. In this manner, the semiconductor crystal layer 106 is transferred onto the second transfer-destination wafer 150, so that a composite wafer that comprises the semiconductor crystal layer 106 disposed on the second transfer-destination wafer 150 is produced.

According to the method of producing a composite wafer of the fifth embodiment, physical property modification is conducted to decrease the adhesiveness between the transfer-destination wafer 120 (the inflexible wafer 126) and the semiconductor crystal layer 106 after the transfer-destination wafer 120 and the second transfer-destination wafer 150 have been bonded, and therefore the adhesiveness can be controlled depending on transfer steps and consequently the transfer process which includes more than one step can be stably performed.

In the same manner as the second embodiment, the fifth embodiment also provides the feature that a physical property of the interface that dominates the adhesiveness of the semiconductor crystal layer 106 and the second transfer-destination wafer 150, in other words, a physical property of the joint interface between the semiconductor crystal layer 106 and the second transfer-destination wafer 150 can be modified so as to increase the adhesiveness, the feature that a physical property of the adhesion layer can be modified when an adhesion layer is provided between the semiconductor crystal layer 106 and the second transfer-destination wafer 150, and the feature that the physical property modification may be modification in the adhesiveness at the interface and modification in the etching resistance.

### Sixth Embodiment

FIGS. 22 through 25 illustrate sectional views illustrating, in order, steps in a method of producing a composite wafer according to a sixth embodiment. In the sixth embodiment, the adhesion layer 160 which is made of an organic material is formed between the semiconductor crystal layer 106 and transfer-destination wafer 120. The producing method of the sixth embodiment has many common features with the producing method of the fourth embodiment, and therefore different features are mainly hereunder described and descriptions of the common features will be omitted.

Referring to FIG. 22, the adhesion layer 160 is further formed after the sacrificial layer 104 and semiconductor crystal layer 106 have been formed on the semiconductor crystal layer formation wafer 102. The adhesion layer 160 is a layer for increasing the adhesiveness between the semiconductor crystal layer 106 and the transfer-destination wafer 120 and is made of an organic material. Because the adhesion layer 160 is made of an organic material, even if the surface of the semiconductor crystal layer 106 has irregularities, minor irregularities are absorbed by the adhesion layer 160 and the semiconductor crystal layer 106 can be bonded to the transfer-destination wafer 120 well. Examples of the adhesion layer 160 include a polyimide film and a resist film. In such cases, the adhesion layer 160 can be formed by an application method such as spin coating. The thickness of the adhesion layer 160 may be in a range of 0.1 nm to 100 μm.

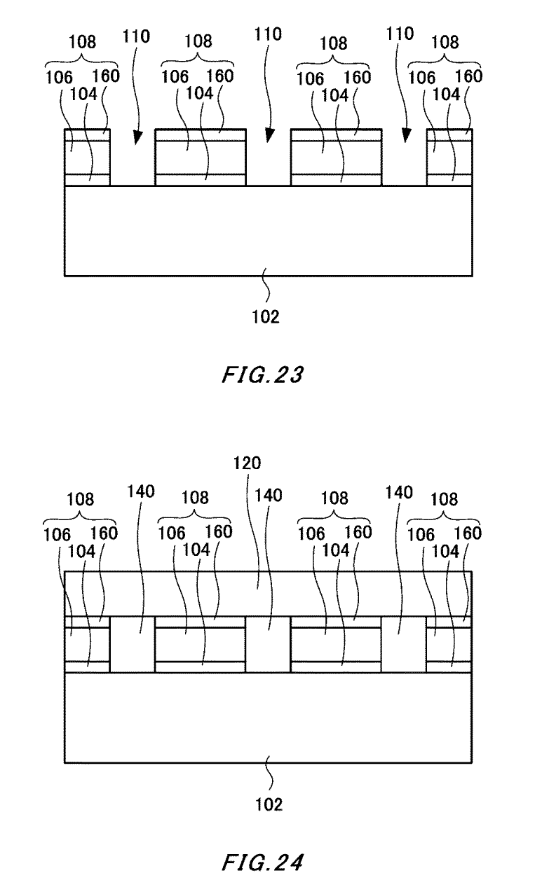

Referring to FIG. 23, the adhesion layer 160 and the semiconductor crystal layer 106 are etched so as to expose a part of the sacrificial layer 104, and the semiconductor crystal layer 106 is divided into a plurality of divided bodies 108. The grooves 110 are formed between two adjacent divided bodies 108 after the etching. The grooves 110 can be formed in the same manner as the fourth embodiment.

Referring to FIG. 24, the front surface of the transfer-destination wafer 120 faces the semiconductor crystal layer 106 of the semiconductor crystal layer formation wafer 102, and the transfer-destination wafer 120 and the semiconductor crystal layer formation wafer 102 are then bonded together. The surfaces of the adhesion layer 160 other than the grooves 110 are an example of “first surfaces” which are the surfaces of a layer formed on the semiconductor crystal layer formation wafer 102 and are to be in contact with the transfer-destination wafer 120 or a layer formed on the transfer-destination wafer 120. The surface of the transfer-destination wafer 120 is an example of “the second surface” which is the surface of the transfer-destination wafer 120 or a layer formed on the transfer-destination wafer 120 and is to be in contact with the first surface. The transfer-destination wafer 120 and the semiconductor crystal layer formation wafer 102 are bonded together such that the surface of the adhesion layer 160, which is the first surface, and the surface of the transfer-destination wafer 120, which is the second surface, are jointed together. Bonding is formed in the same manner as the fourth embodiment. Unlike the fourth embodiment, it is not necessary to provide the organic material layer 128 on the transfer-destination wafer 120. In the sixth embodiment, any type of transfer-destination wafer 120 can be used.

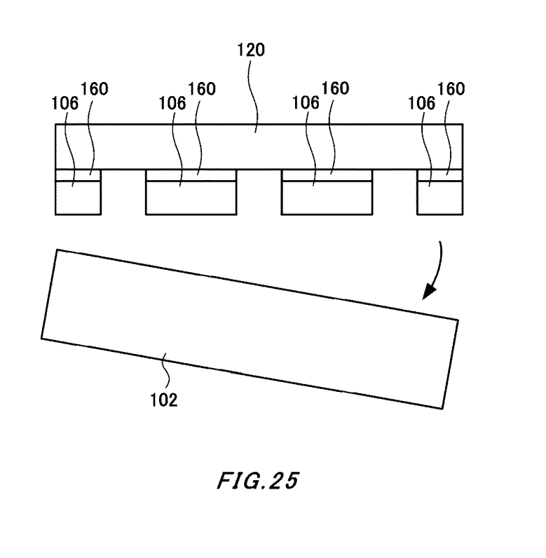

The sacrificial layer 104 is subsequently etched, and the transfer-destination wafer 120 and the semiconductor crystal layer formation wafer 102 are split from each other with the adhesion layer 160 and the semiconductor crystal layer 106 remaining on the transfer-destination wafer 120 side as illustrated in FIG. 25. The splitting is performed in the same manner as the fourth embodiment. In the above-described manner, the adhesion layer 160 and the semiconductor crystal layer 106 are transferred onto the transfer-destination wafer 120, so that a composite wafer that has the adhesion layer 160 and the semiconductor crystal layer 106 disposed on the transfer-destination wafer 120 is produced.

According to the method of producing a composite wafer of the sixth embodiment, the adhesion layer 160 which is made of an organic material is provided, and therefore the adhesion between the transfer-destination wafer 120 and semiconductor crystal layer 106 is secured and the irregulariteis of the surface of the semiconductor crystal layer 106 can be absorbed by the adhesion layer 160. In this way, the level of the flatness required for the semiconductor crystal layer 106 can be lowered.

Furthermore, in the same manner as the fifth embodiment, the semiconductor crystal layer 106 disposed on the transfer-destination wafer 120 can be further transferred onto the second transfer-destination wafer 150 by using the composite wafer of the sixth embodiment. In this case, the adhesion layer 160 can be used as a sacrificial layer when the semiconductor crystal layer 106 is transferred onto the second transfer-destination wafer 150.

Moreover, in the same manner as the third embodiment, after the sacrificial layer 104 and the semiconductor crystal layer 106 have been formed on the semiconductor crystal layer formation wafer 102 and before the semiconductor crystal layer formation wafer 102 and the transfer-destination wafer 120 are bonded together, an electronic device that utilizes a part of the semiconductor crystal layer 106 as an active region may be formed in the semiconductor crystal layer 106.

### REFERENCE EXAMPLE

A GaAs wafer was used as the semiconductor crystal layer formation wafer 102, and an AlAs crystal layer and a Ge crystal layer were formed on the GaAs wafer by an epitaxial growth method utilizing a low-pressure CVD method. The AlAs crystal layer corresponds to the sacrificial layer 104, and the Ge crystal layer corresponds to the semiconductor crystal layer 106. The size of the GaAs wafer was 10 mm×10 mm, and the AlAs crystal layer and the Ge crystal layer were formed on the whole surface of the GaAs wafer. The thickness of the AlAs crystal layer and the Ge crystal layer were 150 nm and 4.8 μm, respectively.

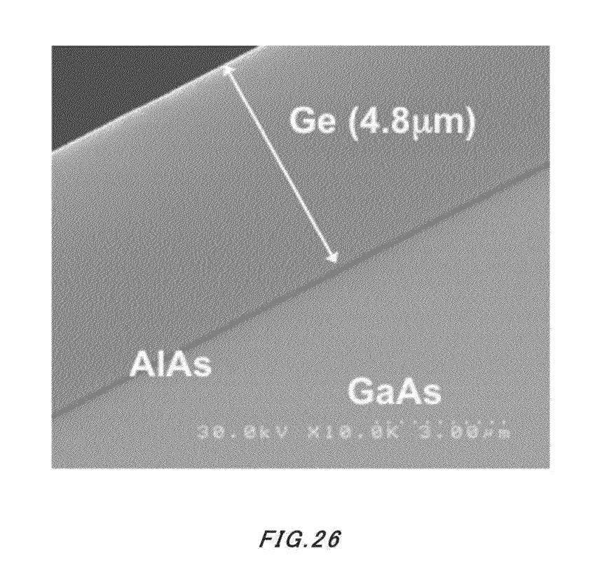

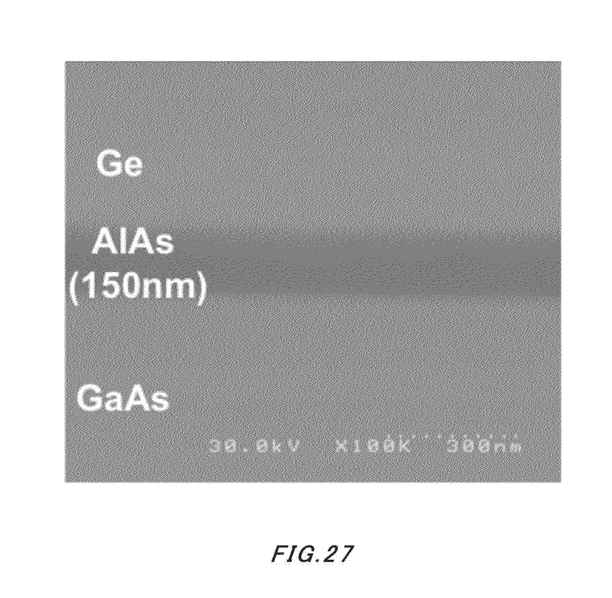

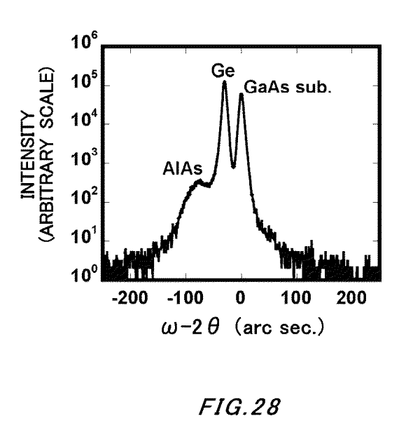

FIG. 26 and FIG. 27 are SEM images of cross sections of the AlAs crystal layer and the Ge crystal layer formed on the GaAs wafer, and FIG. 27 is an enlarged SEM image of a part of the AlAs crystal layer. FIG. 28 is a graph showing an X-ray rocking curve measurement result of the AlAs crystal layer and the Ge crystal layer disposed on the GaAs wafer on a (004) plane. Referring to FIG. 28, clear peaks stemming from the AlAs crystal layer, the Ge crystal layer and the GaAs wafer can be seen in the graph. The full width at half maximum of the peak stemming from the Ge crystal layer was 25.0 (arc sec.), and from this result, it was appreciated that the crystal quality of the Ge crystal layer was very fine.

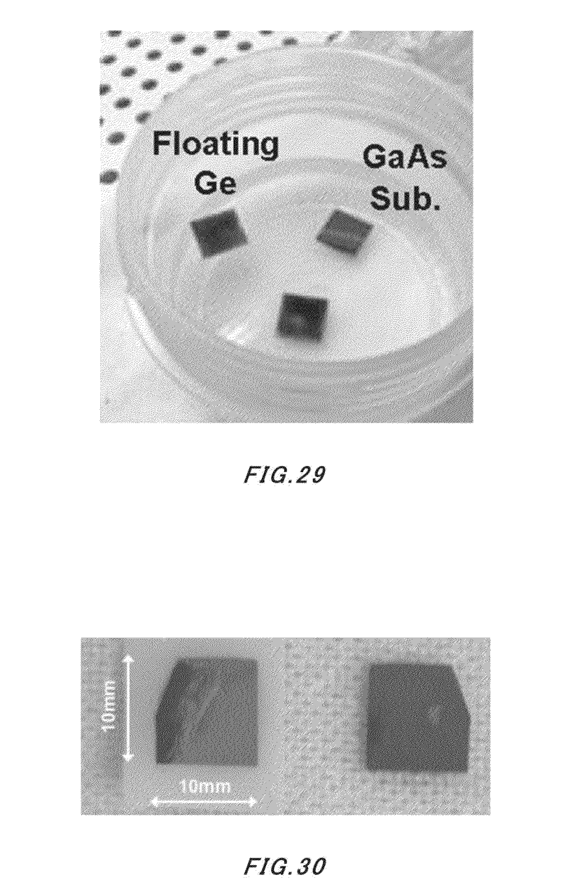

FIG. 29 shows a picture of a GeAs wafer on which the AlAs crystal layer and the Ge crystal layer had been formed and the GeAs wafer was immersed in 49% HF solution and left for 5 hours at room temperature. The AlAs crystal layer was dissolved with the 49% HF solution, and the Ge crystal layer was split from the GaAs wafer. The picture shows that the split Ge crystal layer was floating in the HF solution. More specifically, it was demonstrated that even the Ge crystal layer having a die size of about 10 mm×10 mm could be clearly separated with the 49% HF solution when the AlAs crystal layer having a thickness of 150 nm was used as the sacrificial layer 104, and the effectiveness of the epitaxial lift-off (ELO) was confirmed. Note here that the split Ge crystal layer is subject to breakage, and therefore it is preferable that when the Ge crystal is transferred onto other wafer the epitaxial lift-off method be applied after the Ge crystal layer has been transferred onto the destination wafer.

After the AlAs crystal layer and the Ge crystal layer have been formed on the GaAs wafer, a flexible plastic wafer (the transfer-destination wafer 120) was bonded to the Ge crystal layer side, and after the plastic wafer had been bonded, the plastic wafer/the Ge crystal layer/the AlAs crystal layer/the GeAs wafer was immersed in the 49% HF solution. The bonded wafers were immersed for five hours at room temperature to dissolve the AlAs crystal layer, and the plastic wafer/the Ge crystal layer and the GaAs wafer were split from each other.

FIG. 30 shows a Ge crystal layer bonded on a plastic substrate (the left picture) and a GaAs wafer from which a Ge crystal layer has been split away (the right picture). It was demonstrated that a fine Ge crystal layer with a die size of about 10 mm×10 mm was formed on the plastic wafer by using the above-described method (the epitaxial lift-off method: the ELO method). Any material can be used for the wafer provided that the material is not dissolved with an etchant (in this example, the HF solution) which is used for the crystalline sacrificial layer (the AlAs crystal layer in this example). Therefore, it is possible to form a fine Ge crystal layer on any wafers.

### Example 1

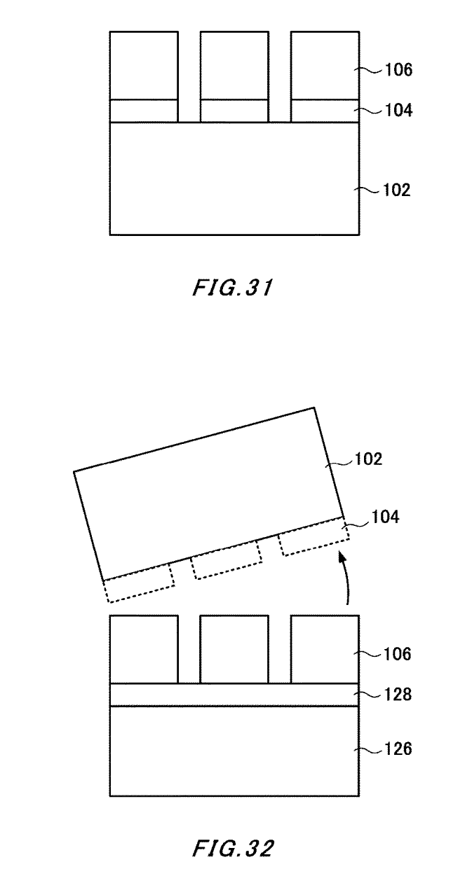

In Example 1, a case where a Ge crystal layer having a device size smaller than 100 μm×100 μm is formed by the ELO method will be described. Referring first to FIG. 31, the sacrificial layer 104 and the semiconductor crystal layer 106 were sequentially formed on the semiconductor crystal layer formation wafer 102 by an epitaxial crystal growth method. The semiconductor crystal layer 106 is then pattered in a dimension of 50 μm×50 μm. A GaAs wafer is used as the semiconductor crystal layer formation wafer 102, and an AlAs crystal layer is used as the sacrificial layer 104. The thickness of the AlAs crystal layer was 150 nm. A Ge crystal layer was adopted as the semiconductor crystal layer 106. A reactive ion etching method (RIE method) was used to pattern the Ge crystal layer. After the patterning of the Ge crystal layer, the AlAs crystal layer was patterned by immersing the wafer in pure water.

A silicon wafer was used as the inflexible wafer 126, and a polyimide film was formed on the silicon wafer as the organic material layer 128 by a spin-coating method. The polyimide film served as an adhesion layer. The GaAs wafer (the semiconductor crystal layer formation wafer 102) and the inflexible wafer 126 (the transfer-destination wafer) were bonded together such that the patterned Ge crystal layer (the semiconductor crystal layer 106) was in contact with the polyimide film (the organic material layer 128). Referring next to FIG. 32, the AlAs crystal layer (the sacrificial layer 104) was dissolved with 49% HF solution to split the Ge crystal layer and the GaAs wafer from each other. The dissolution of the AlAs crystal layer with the 49% HF solution (separation of the Ge crystal layer from the GaAs wafer) was achieved for less than 10 minutes. The etching time of 10 minutes was considered as sufficiently practicable.

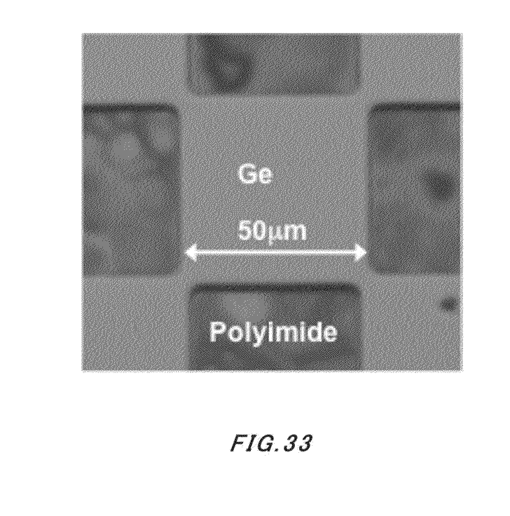

FIG. 33 is an optical microscope image observing the patterned Ge crystal layer which had been transferred onto the silicon wafer with the polyimide film. The Ge crystal layer shown in FIG. 33 has a device region with a dimension of 50 μm×50 μm, and has a planar shape in which four corners of the device region are in contact with other Ge crystal layer regions. In other words, it can be seen from FIG. 33 that the Ge crystal layer was clearly transferred even with the constricted area such as the four corners without damaging the Ge crystal layer and the fine structural pattern of the Ge crystal layer was secured. As described above, by applying the ELO method, even after the Ge crystal layer has been patterned, the Ge crystal layer can be transferred onto the transfer-destination wafer 120 while maintaining the pattern shape.

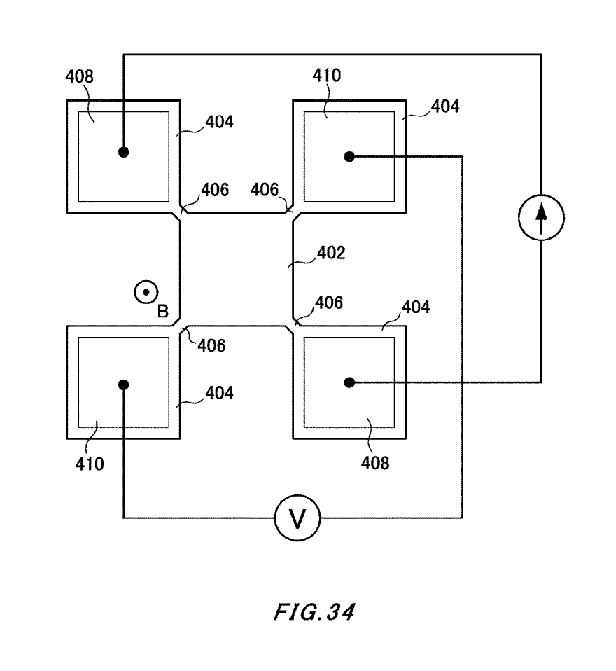

The transferred Ge crystal layer can be processed into a semiconductor device such as a Hall device. FIG. 34 illustrates an example in which the Ge crystal layer of FIG. 33 is applied to a Hall device. The Ge crystal layer has a device region 402 with a dimension of 50 μm×50 μm. An electrode region 404 is formed at each of the four corners of the device region 402. The device region 402 and the electrode region 404 are connected to each other via a connecting section 406 that has a narrow width. Current is applied to one of two pairs of the electrodes which are arranged in diagonals, which here is the pair of the electrodes 408, and a voltage generated between the other of the two pairs of the electrodes, which is the pair of the electrodes 410, is measured to determine the strength of a magnetic field B.

### Example 2

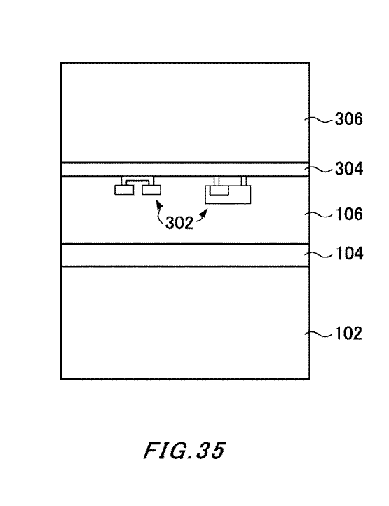

In Example 2, a case where a device is processed on a Ge crystal layer and the Ge crystal layer is transferred onto a glass substrate by using the ELO method will be described. Referring to FIG. 35, an AlAs crystal layer as the sacrificial layer 104 and a Ge crystal layer as the semiconductor crystal layer 106 were formed on a GaAs wafer which is the semiconductor crystal layer formation wafer 102. A device 302 such as a p-channel MOSFET, a diode and resistor was then formed in the Ge crystal layer, and a transfer-destination silicon wafer 306 was bonded to the GaAs wafer with an adhesion layer 304. The silicon wafer 306 was an intermediate wafer used for transfer.

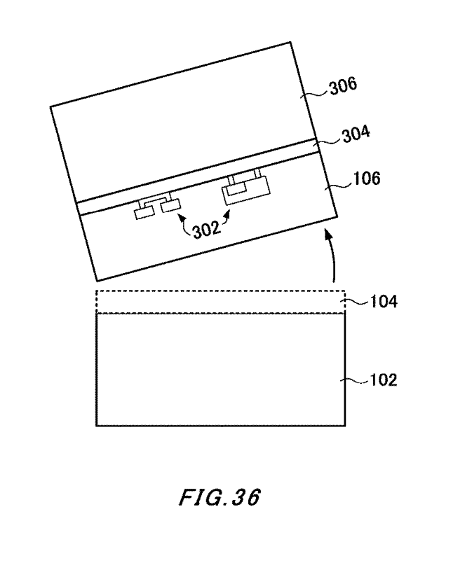

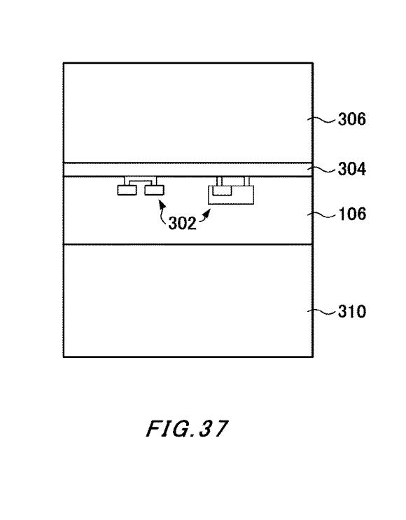

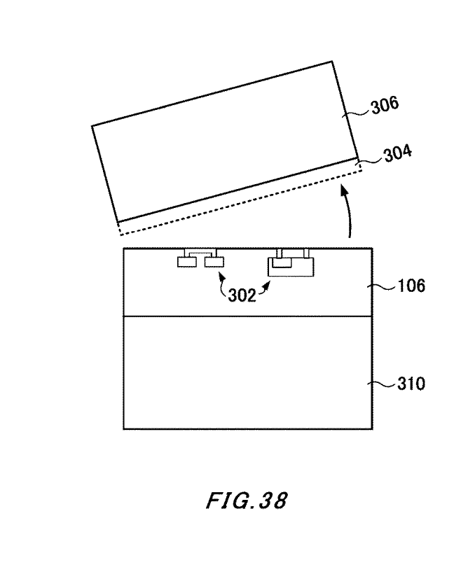

Referring to FIG. 36, the AlAs layer (the sacrificial layer 104) was dissolved with an HF solution to split the Ge crystal layer and the GaAs wafer. Referring to FIG. 37, a glass substrate was used as a base wafer 310, and the glass substrate (the base wafer 310) and the Ge crystal layer (the semiconductor crystal layer 106) were bonded together using van der Waals attraction. Referring next to FIG. 38, the adhesion layer 304 was dissolved or detached to split the Ge crystal layer from the silicon wafer 306. In the above described manner, the Ge crystal layer in which the device was formed as transferred to the base wafer 310 which was the target wafer via the silicon wafer 306 which was the intermediate wafer.

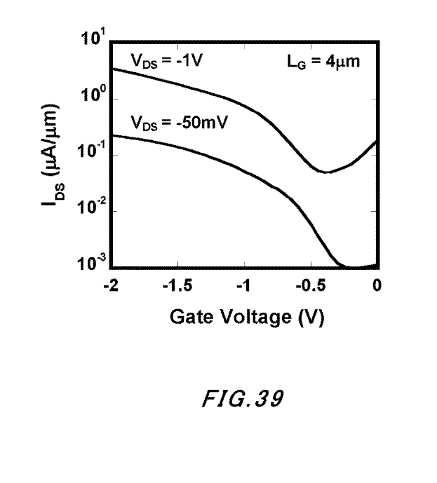

FIG. 39 illustrates an I_{DS}-V_{G} characteristic of a p-channel MOSFET that is one of the elements 302 formed in the Ge crystal layer transferred onto the glass substrate. The gate length of the p-channel MOSFET was 4 μm. FIG. 39 illustrates the cases where V_{DS} were −1 V and −50 mV. As shown in FIG. 39, the on/off ratio of a source-drain current reached double digits or more, and it was demonstrated that the element was not destroyed and operated normally even after the ELO method was applied.

Although the producing method has been mainly described in the above embodiments and examples, the present invention can also be understand as a composite wafer produced by the above-described method. More specifically, the present invention also provides a composite wafer that includes a flexible wafer (the transfer-destination wafer 120) and the single-crystal semiconductor layer 106 that is arranged in contact with the flexible wafer. In addition, the present invention provides a composite wafer that includes the inflexible wafer 126, the single-crystal semiconductor layer 106, and the organic material layer 128 that is provided between the inflexible wafer 126 and the semiconductor crystal layer 106. When the semiconductor crystal layer 106 is a single-crystal Ge layer, the full width at half maximum of a diffraction spectrum of the single-crystal Ge layer measured using an X-ray diffraction method may be 40 arcsec or less. Moreover, an electronic device having a part of the single-crystal Ge layer as an active region may be processed on the single-crystal Ge layer. Examples of such an electronic device include a Hall device.

Although a wafer onto which the semiconductor crystal layer 106 is to be ultimately transferred has not been described in the above embodiments and examples, examples of such wafer include a semiconductor wafer such as a silicon wafer, an SOI wafer, and an isolative wafer on which a semiconductor layer is formed. Moreover, an electronic device such as a transistor may be formed in advance on the semiconductor wafer, the SOI layer or the semiconductor layer. In other words, the semiconductor crystal layer 106 can be formed by transferring the semiconductor crystal layer to a wafer on which an electronic device has been already formed by using the above-described method. In this way, semiconductor devices which are made of different materials or composition ratios can be monolithically fabricated. In particular, electronic devices that have different kinds of materials and are manufactured through different manufacturing processes can be fabricated easily and monolithically when an electronic device is formed in advance in the semiconductor crystal layer 106 and then the semiconductor crystal layer 106 is transferred onto a wafer in which another electronic device has been formed. Note that the phrase “a layer on the wafer” may encompass not only a layer formed in contact with the wafer but also a layer which is not in direct contact with the wafer but with other layer interposed therebetween.

1. A method for producing a composite wafer including a semiconductor crystal layer, the method comprising:
forming, in order, a sacrificial layer and the semiconductor crystal layer directly or indirectly on a semiconductor crystal layer formation wafer;
bonding together the semiconductor crystal layer formation wafer and a transfer-destination wafer such that a first surface and a second surface face each other, the first surface being a surface of any layer formed directly or indirectly on the semiconductor crystal layer formation wafer, and the second surface being a surface of the transfer-destination wafer or of any layer formed directly or indirectly on the transfer-destination wafer and is to be in contact with the first surface; and
splitting the transfer-destination wafer from the semiconductor crystal layer formation wafer with the semiconductor crystal layer remaining on the transfer-destination wafer side, by etching away sacrificial layer by immersing the semiconductor crystal layer formation wafer and the transfer-destination wafer wholly or partially in an etchant, and
wherein the transfer-destination wafer comprises an inflexible wafer and an organic material layer, and the surface of the organic material layer is the second surface.

2. A method for producing a composite wafer including a semiconductor crystal layer, the method comprising:
forming, in order, a sacrificial layer and the semiconductor crystal layer directly or indirectly on a semiconductor crystal layer formation wafer;
forming, directly or indirectly on the semiconductor crystal layer, an adhesion layer made of an organic material;
bonding together the semiconductor crystal layer formation wafer and a transfer-destination wafer such that a first surface, which is a surface of the adhesion layer, and a second surface, which is a surface of the transfer-destination wafer or of an layer formed directly or indirectly on the transfer-destination wafer and is to be in contact with the first surface, face each other; and
splitting the transfer-destination wafer from the semiconductor crystal layer formation wafer with the semiconductor crystal layer remaining on the transfer-destination wafer side, by etching away sacrificial layer by immersing the semiconductor crystal layer formation wafer and the transfer-destination wafer wholly or partially in an etchant.

3. The method according to claim 1 of producing a composite wafer comprising a semiconductor crystal layer, wherein the semiconductor crystal layer comprises GeₓSi₁₋ₓ (0<x≦1).

4. The method according to claim 1 of producing a composite wafer comprising a semiconductor crystal layer, wherein the thickness of the semiconductor crystal layer is equal to or larger than 0.1 nm and smaller than 1 μm.

5. The method according to claim 1 of producing a composite wafer comprising a semiconductor crystal layer, further comprising:
after forming the sacrificial layer and the semiconductor crystal layer and before bonding together the semiconductor crystal layer formation wafer and the transfer-destination wafer, etching at least the semiconductor crystal layer to expose the sacrificial layer partially and dividing the semiconductor crystal layer into a plurality of divided bodies.

6. The method according to claim 1 of producing a composite wafer comprising a semiconductor crystal layer, further comprising:
after splitting the transfer-destination wafer from the semiconductor crystal layer formation wafer, bonding together the transfer-destination wafer and a second transfer-destination wafer such that the semiconductor crystal layer side of the transfer-destination wafer and a front surface side of the second transfer-destination wafer face each other;
modifying a physical property of the organic material layer located between the transfer-destination wafer and the semiconductor crystal layer; and
splitting the second transfer-destination wafer from the transfer-destination wafer with the semiconductor crystal layer remaining on the second transfer-destination wafer side.

7. The method according to claim 6 of producing a composite wafer comprising a semiconductor crystal layer,
wherein the modifying the physical property comprises swelling the organic material layer by immersing, in an organic solvent, the transfer-destination wafer and the second transfer-destination wafer that are bonded together, or curing the organic material layer by heat or ultraviolet rays.

8. The method according to claim 6 of producing a composite wafer comprising a semiconductor crystal layer, further comprising:
before spritting the second transfer-destination wafer from the transfer-destination wafer, modifying one or more physical properties selected from a physical property of an interface that dominates adhesive property between the transfer-destination wafer and the semiconductor crystal layer, a physical property of a layer located between the semiconductor crystal layer and the second transfer-destination wafer, and a physical property of an interface that dominates adhesive property between the semiconductor crystal layer and the second transfer-destination wafer.

9. The method according to claim 1 of producing a composite wafer comprising a semiconductor crystal layer, further comprising:
after forming the sacrificial layer and the semiconductor crystal layer and before bonding together the semiconductor crystal layer formation wafer and the transfer-destination wafer, forming, in the semiconductor crystal layer, an electronic device which includes a portion of the semiconductor crystal layer as an active region.

10. A composite wafer comprising:
an inflexible wafer;
a single-crystal semiconductor crystal layer; and
an organic material layer located between the inflexible wafer and the semiconductor crystal layer.

11. The composite wafer according to claim 10, wherein the semiconductor crystal layer comprises GeₓSi₁₋ₓ (0<x≦1).

12. The composite wafer according to claim 10, wherein the thickness of the semiconductor crystal layer is equal to or larger than 0.1 nm and smaller than 1 μm.

13. The composite wafer according to claim 11, wherein the semiconductor crystal layer is a single-crystal Ge layer, and the full width at half maximum of a diffraction spectrum of the single-crystal Ge layer measured using an X-ray diffraction method is 40 arcsec or less.

14. The composite wafer according to claim 13, wherein an electronic device that comprises a portion of the single-crystal Ge layer as an active region is formed in the single-crystal Ge layer.
